(19) United States
(12) Patent Application Publication
(10) Pub. No.: US 2005/0276992 A1
(43) Pub. Date: Dec. 15, 2005

(54) Method for metallizing a non-metallic surface and the metallized surface structure thereof

(76) Inventor: Tung-Hsin Wu, I-Lan Hsien (TW)

Correspondence Address: NIKOLAI & MERSEREAU, P.A., 900 SECOND AVENUE SOUTH, SUITE 820, MINNEAPOLIS, MN, 55402, US

(21) Appl. No.: 10/864,133

(22) Filed: Jun. 9, 2004

(51) Int. Cl. B32B 15/08; C23C 14/00; B05D 7/00

(52) U.S. Cl. 428/626; 427/402; 204/192.1

(57) ABSTRACT

A method for metallizing a non-metallic surface includes plating a basic metallic plating film on a non-metallic surface, plating a first metallic material on a surface of the basic metallic plating film to form an inner metallic layer, and plating a second metallic material on a surface of the inner metallic layer to form an outer metallic layer. Thus, the thin basic metallic plating film is previously plated on the non-metallic surface in a vacuum sputtering manner, so that the non-metallic surface is electrically conductive, thereby decreasing the working time of the later chemically or electrically plating steps, and thereby enhancing the productivity.

### BACKGROUND OF THE INVENTION

1. Field of the Invention

The present invention relates to a method for metallizing a non-metallic surface and the metallized surface structure thereof.

2. Description of the Related Art

A conventional method for metallizing a non-metallic surface in accordance with the prior art shown in FIG. 2 comprises an injecting conductive oil step 101 to inject conductive oil onto a non-metallic surface, a drying step 102 to dry the surface of the non-metallic surface, a washing step 103 to wash the surface of the non-metallic surface, a plating copper step 104 to plate the copper onto the surface of the non-metallic surface, a washing step 105 to wash the surface of the copper, a plating nickel step 106 to plate the nickel onto the surface of the copper, a washing step 107 to wash the surface of the nickel, a roughing step 108 to use the chromium acid to rough the surface of the nickel, a washing step 109 to wash the surface of the nickel, and a drying step 110 to dry the surface of the nickel, thereby finishing the working process.

In such a manner, the surface of the non-metallic surface is coated with the copper and the nickel, so that the metallized surface structure formed by the conventional method has a smaller resistance and a greater thickness. However, the conventional method needs to employ the chromium aid and the conductive oil, thereby easily incurring the environmental pollution, so that the conventional method does not satisfy requirements of the environmental protection.

### SUMMARY OF THE INVENTION

In accordance with one embodiment of the present invention, there is provided a method for metallizing a non-metallic surface, comprising:
a first step to plate a basic metallic plating film on a non-metallic surface;
a second step to plate a first metallic material on a surface of the basic metallic plating film to form an inner metallic layer; and
a third step to plate a second metallic material on a surface of the inner metallic layer to form an outer metallic layer.

In accordance with another embodiment of the present invention, there is provided a metallized surface structure, comprising:
a non-metallic surface;
a basic metallic plating film mounted on the non-metallic surface;
an inner metallic layer mounted on a surface of the basic metallic plating film; and
an outer metallic layer mounted on a surface of the inner metallic layer to form a protective layer.

The primary objective of the present invention is to provide a method for metallizing a non-metallic surface and the metallized surface structure thereof, wherein the thin basic metallic plating film is previously plated on the non-metallic surface in a vacuum sputtering manner, so that the non-metallic surface is electrically conductive, thereby decreasing the working time of the later chemically or electrically plating steps, and thereby enhancing the productivity.

Another objective of the present invention is to provide a method for metallizing a non-metallic surface and the metallized surface structure thereof, wherein the metallizing method needs not to employ the chromium aid or conductive oil, thereby reducing the environmental pollution so as to satisfy requirements of the environmental protection.

A further objective of the present invention is to provide a method for metallizing a non-metallic surface and the metallized surface structure thereof, wherein the surface of the basic metallic plating film is provided with an inner metallic layer and an outer metallic layer to increase the thickness of the metallized surface structure, thereby enhancing the conductive effect and the outer appearance of the metallized surface structure.

Further benefits and advantages of the present invention will become apparent after a careful reading of the detailed description with appropriate reference to the accompanying drawings.

### BRIEF DESCRIPTION OF THE DRAWINGS

FIG. 1 is a flow chart of a method for metallizing a non-metallic surface in accordance with the preferred embodiment of the present invention; and

FIG. 2 is a flow chart of a conventional method for metallizing a non-metallic surface in accordance with the prior art.

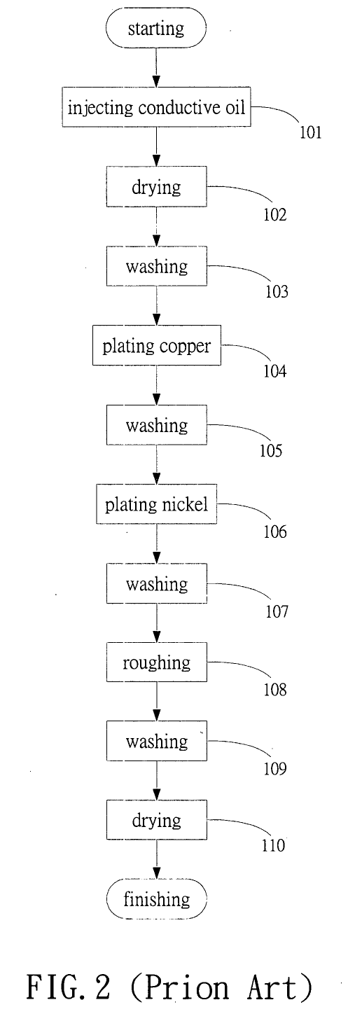

### DETAILED DESCRIPTION OF THE INVENTION

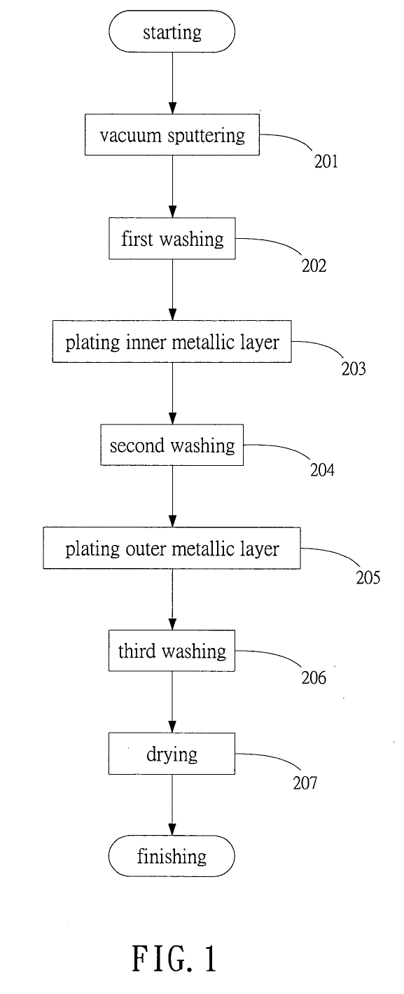

Referring to FIG. 1, a method for metallizing a non-metallic surface in accordance with the preferred embodiment of the present invention comprises:
a vacuum sputtering step 201 to plate a thin basic metallic plating film on a non-metallic surface (such as the surface of plastic material) in a vacuum sputtering manner, so that the non-metallic surface is electrically conductive;
a first washing step 202 to wash a surface of the basic metallic plating film;
a plating inner metallic layer step 203 to plate a first metallic material on the surface of the basic metallic plating film to form an inner metallic layer;
a second washing step 204 to wash a surface of the inner metallic layer;
a plating outer metallic layer step 205 to plate a second metallic material on the surface of the inner metallic layer to form an outer metallic layer;
a third washing step 206 to wash a surface of the outer metallic layer; and
a drying step 207 to dry the surface of the outer metallic layer, thereby finishing the working process.

Preferably, in the plating inner metallic layer step 203, the first metallic material is a metal having greater attractive feature, such as the copper. In addition, the first metallic material is plated on the surface of the basic metallic plating film in a chemically plating manner or an electrically plating manner.

Preferably, in the plating outer metallic layer step 205, the second metallic material is a metal having greater hardness, such as the nickel, so as to provide a protective effect. Alternatively, the second metallic material is a wear-resistant, oxidation-resistant and conductive metal, such as the stainless steel or chromium. In addition, the second metallic material is plated on the surface of the inner metallic layer in a chemically plating manner or an electrically plating manner.

In such a manner, a metallized surface structure in accordance with the preferred embodiment of the present invention comprises a non-metallic surface, a basic metallic plating film mounted on the non-metallic surface, an inner metallic layer mounted on a surface of the basic metallic plating film, and an outer metallic layer mounted on a surface of the inner metallic layer to form a protective layer.

Accordingly, a thin basic metallic plating film is previously plated on the non-metallic surface in a vacuum sputtering manner, so that the non-metallic surface is electrically conductive, thereby decreasing the working time of the later chemically or electrically plating steps, and thereby enhancing the productivity. In addition, the metallizing method needs not to employ the chromium aid or conductive oil, thereby reducing the environmental pollution so as to satisfy requirements of the environmental protection. Further, the surface of the basic metallic plating film is provided with an inner metallic layer and an outer metallic layer to increase the thickness of the metallized surface structure, thereby enhancing the conductive effect and the outer appearance of the metallized surface structure.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A method for metallizing a non-metallic surface, comprising:
a first step to plate a basic metallic plating film on a non-metallic surface;
a second step to plate a first metallic material on a surface of the basic metallic plating film to form an inner metallic layer; and
a third step to plate a second metallic material on a surface of the inner metallic layer to form an outer metallic layer.

2. The method in accordance with claim 1, wherein the basic metallic plating film is plated on the non-metallic surface in a vacuum sputtering manner, so that the non-metallic surface is electrically conductive.

3. The method in accordance with claim 1, wherein the first metallic material is a metal having greater attractive feature.

4. The method in accordance with claim 1, wherein the first metallic material is copper.

5. The method in accordance with claim 1, wherein the first metallic material is plated on the surface of the basic metallic plating film in a chemically plating manner.

6. The method in accordance with claim 1, wherein the first metallic material is plated on the surface of the basic metallic plating film in an electrically plating manner.

7. The method in accordance with claim 1, wherein the second metallic material is a metal having greater hardness.

8. The method in accordance with claim 1, wherein the second metallic material is nickel.

9. The method in accordance with claim 1, wherein the second metallic material is a wear-resistant, oxidation-resistant and conductive metal.

10. The method in accordance with claim 1, wherein the second metallic material is a stainless steel.

11. The method in accordance with claim 1, wherein the second metallic material is chromium.

12. The method in accordance with claim 1, wherein the second metallic material is plated on the surface of the inner metallic layer in a chemically plating manner.

13. The method in accordance with claim 1, wherein the second metallic material is plated on the surface of the inner metallic layer in an electrically plating manner.

14. A metallized surface structure, comprising:
a non-metallic surface;
a basic metallic plating film mounted on the non-metallic surface;
an inner metallic layer mounted on a surface of the basic metallic plating film; and
an outer metallic layer mounted on a surface of the inner metallic layer to form a protective layer.

15. The metallized surface structure in accordance with claim 14, wherein the basic metallic plating film is plated on the non-metallic surface in a vacuum sputtering manner, so that the non-metallic surface is electrically conductive.

16. The metallized surface structure in accordance with claim 14, wherein the first metallic material is copper.

17. The metallized surface structure in accordance with claim 14, wherein the second metallic material is nickel.

18. The metallized surface structure in accordance with claim 14, wherein the second metallic material is a stainless steel.

19. The metallized surface structure in accordance with claim 14, wherein the second metallic material is chromium.
